(19) United States
(12) Patent Application Publication
(10) Pub. No.: US 2025/0030225 A1
(43) Pub. Date: Jan. 23, 2025

(54) APPARATUS AND METHODS FOR ACTIVE ZONE DEPLOYMENT

(71) Applicant: Panduit Corp., Tinley Park, IL (US)

(72) Inventors: Jose M. Castro, Naperville, IL (US); Bulent Kose, Burr Ridge, IL (US); George F. Einterz, Schererville, IN (US); Kevin A. Marley, Joliet, IL (US); Brian L. Kelly, Oak Forest, IL (US)

(73) Assignee: Panduit Corp., Tinley Park, IL (US)

(21) Appl. No.: 18/222,741

(22) Filed: Jul. 17, 2023

(51) Int. Cl. H02B 1/20; H05K 7/18

(52) U.S. Cl. CPC H02B 1/202; H05K 7/186

(57) ABSTRACT

A method and apparatus for repurposing a communications zone enclosure including providing an input power source within a telecommunications room, providing circuitry configured to split the power of the input source into a plurality of channels, using preexisting twisted pair communication cables to transmit power from the plurality of channels to the zone enclosure, and recombining power the power into a single output power source.

### FIELD OF INVENTION

The present invention relates to the field of efficient power transmission over data network interconnections, using copper communication cables and optical fiber cables.

### BACKGROUND

Traditionally, enterprise networks have used copper connectivity such as unshielded twisted pair (UTP) of different levels of performance, e.g., Cat. 5, Cat. 6, or Cat 6 A, specified by the Telecommunications Industry Association (TIA). However, copper connectivity confines the Ethernet network distances to 100 m and has reached the point where achieving power-efficient transmission at data rates beyond 10 G over 100 m of the copper cable becomes challenging and, in some cases, impractical. Since the last decade, enterprise networks have been experiencing an accelerated migration from wired to wireless connections. It is expected that by the end of this decade more than 95% of enterprise traffic will be carried by wireless access. Newer wireless access points (WAP) (Wi-Fi 6E and Wi-Fi 7) and newer cellular bands in 5G (e.g., NR) will require extended wired high-bandwidth channels, which impose challenges to traditional copper, UTP, or coaxial media.

On the other hand, optical networks can provide secure and virtually limitless bandwidth for very long distances that can cover the requirement of premises and campus networks from core to access layers. In the subsequent years, many businesses need to upgrade their local area networks (LAN) and campus networks to remain competitive. Currently, a considerable number of UTP networks use zone cabling (ZC). A ZC uses horizontal cables (HC) to connect the telecommunications room (TR) to consolidation points (CPs) located at a more convenient distance from the service devices. CPs can be placed in zone enclosures (ZE) installed on the wall, ceiling, or below the floor, providing flexibility, and facilitating changes or upgrades of work areas (WAS) connections. Using ZC provides several advantages. For instance, ZC facilitates the convergence of Information Technology (IT) data, voice networks, wireless (Wi-Fi), and Operational Technology (OT), including lighting and security, sensor, and control devices. Also, ZC provides high flexibility for reorganizing the network.

ZC can be classified as passive ZC (PZC) and active ZC (AZC). In PZC, there is no active equipment in the ZE, and switches are centralized in the TR. The value of PZC is to facilitate the cabling organization, which is important for companies where the WAs need to be reconfigured frequently.

AZCs provide even more advantages than PZCs by moving the switching and power source to a ZE near the end device. In AZC, there is usually a Power over Ethernet (POE) switch that serves a lesser number of end devices, which in many cases becomes more cost-effective than having larger switches in the TR. By moving the active equipment to the ZE, the TR size can be reduced since it only houses patching components. Moreover, when fiber, instead of UTP is used, it becomes easier to service multiple ZEs with a TR and reduce the number of TRs per installation. AZC also enables more efficient communication from the ZE to the edge device, since moving the POE switch closer to the end device reduces energy loss in cables.

Although migration from PZC to AZC offers several performance advantages, it requires major changes when power is not available near the ZE. In those cases, the TR needs to provide power (PoE or DC) to the AZC using a hybrid cable, consisting of copper pairs and fibers. Brownfield installations are likely to have a plurality of UTP connections between the TR to the PZC as illustrated in FIG. 1. For data transmission, most of those cables can be replaced by a small-diameter optical cable, as shown in FIG. 2, providing a higher bandwidth and more power efficient channel between the TR and ZE than the one provided by several UTP cables. The migration from PZC to AZC brings many performance advantages, but also the challenge of what to do with the amount of unused UTP cables.

Uninstalling those cables is not a trivial process. Sometimes, when factors such as removal cost, risk of damaging other cables in the same cabling routing system, pollution, health hazards associated with the removal process, and disruption of the building operation are considered, the best decision is to leave the inactive cables in place. In other cases, where decommissioned cables should be removed, the environmental impact needs to be considered. Although there are recycling programs to recover copper or even plastic from the cable, the reality is that the energy employed for removing, transporting, selecting, and recycling cables, has an important environmental impact.

It would be desirable for environmental and economical reasons, to reuse the already installed UTP cables to reduce environmental impact. For high data rate transmission, this is impractical since the UTP cable bandwidth is several orders of magnitude lower bandwidth than optical fibers. Even for current data rates of 10G, optical fiber is significantly more power efficient, has >100× longer reaches, fewer errors, requires less complex digital signal processing, smaller diameter cables, and less processing latency. Moving to higher data rates only increases the advantages of fiber optics systems.

As will be described by the authors in this disclosure, perhaps the best way to reuse a vast amount of copper communication cables already installed in enterprise networks is to fully remove them from data transmission operations and dedicate them to transmitting power with high efficiency.

Currently, PoE is a widely deployed method for transmitting power over copper twisted pair cables (CTPC), e.g., UTP cables. PoE allows a CTPC to provide both data connection and electrical power to devices such as wireless access points (WAPs), Internet Protocol (IP) cameras, and Voice-over-Internet Protocol (VOIP) phones. Different generations of PoE have been developed by IEEE task forces such as 802.3af, 802.3 at, 802.3bt that specify different levels of power, maximum voltages, and efficiencies.

For example, in Table 1 (shown in FIG. 11), the power levels for eight Power Sourcing Equipment (PSE) and powered device (PD) classes are shown. The PSE power is the power supplied to the Ethernet cable, whereas the PD power is the power available to the device, after the cable losses. It should be noted that the efficiency metric in this table and the rest of the disclosure (unless it is specifically referred to power source units) only relates to losses in the cable, and therefore, is computed as the ratio between the PD available power and the PSE supplied power. This table based on IEEE PoE standards focuses on the maximum level of power and worst-case efficiencies of the system. Depending on the world region where the network is deployed, additional restrictions and conditions for the maximum power launch need to be considered.

In the US, the National Fire Protection Association (NFPA), provides the National Electrical Code (NEC) or NFPA 70, a standard for the safe installation of electrical wiring and equipment. In 2017, NEC introduced new material in articles 725 and 840 that deal with premise-powered copper-based communication systems, which impact PoE operation, in particular, PoE types higher than 4 and classes higher than 6 (PoE++).

The new article 725.144 introduces an ampacity table, which shows the maximum permitted current per conductor, for a conductor size and a given cable deployment configuration. In this context “deployment configuration” refers to the cable bundle sizes which range from one cable to 192. Article 725.155 also introduces the concept of a Limited Power (LP) cable, which operates at its rated current, without exceeding its rated temperature under a worst-case deployment configuration (192-bundle). The requirements for testing LP cable can be found in Underwriters Laboratories (UL) standards, UL444. For illustration purposes, an LP cable rated for 0.5 amps per conductor and rated temperature of 75 C should be able to transmit 0.5 amps per conductor while maintaining its temperature below 75 C in a 192-bundle configuration. Note that all cables surrounding the cable under test should also transmit similar currents. Applying these new NEC articles, the practical limit for transmitting power using PoE is below 60 W unless the cable is LP certified. For a UTP with 24 AWG conductor, rated 75 C, this power restriction is approximate to constraint the current to ≤0.4 A

The value of reusing CTPC, e.g., UTP, under the PoE constraints mentioned above, highlights the opportunities for a new PSE. A new PSE that can remove complexities required for high bandwidth data transmission over copper and focuses on power transmission over multiple horizontal cables that have already been installed can be less complex and more efficient. This new PSE will operate in conjunction with a new Power Receiver PR, to measure and limit the power to less than 60 W per cable. The new PSE and PR apparatuses and related methods described in this disclosure can reduce CAPEX/OPEX and reduce the environmental impact of the communication system upgrades.

### SUMMARY

A method and apparatus for repurposing a communications zone enclosure including providing an input power source within a telecommunications room, providing circuitry configured to split the power of the input source into a plurality of channels, using preexisting twisted pair communication cables to transmit power from the plurality of channels to the zone enclosure, and recombining power the power into a single output power source.

### BRIEF DESCRIPTION OF THE DRAWINGS

FIG. 1 shows structured cabling from telecom room to a passive zone.

FIG. 2 shows a method to upgrade the zone, from a passive to active zone by reusing the copper twisted pair structured cabling shown in FIG. 1.

FIG. 3A shows a front view of the multi-port power transmitter.

FIG. 3B shows a top view of the multi-port power transmitter.

FIG. 4A shows a front view of the multi-port power receiver.

FIG. 4B shows a rear view of the multi-port power receiver.

FIG. 4C shows a top view of the multi-port power receiver.

FIG. 5 shows schematics of the multi-port transmitter.

FIG. 6A shows schematics for a power supply.

FIG. 6B shows schematics for a power supply similar to FIG. 6A but replaces the diode with another switching element.

FIG. 7 shows diagrams and connections of transmitter module 200 and receiver module.

FIG. 8A shows the front-end configuration for the connection configuration of FIG. 7.

FIG. 8B shows an alternative front-end configuration to that of FIG. 8A.

FIG. 9A shows power transmission as a function of the number of twisted pair cables at a temperature of 25° C. and a current of 0.35 A.

FIG. 9B shows power transmission as a function of the number of twisted pair cables at a temperature of 45° C. and a current of 0.35 A.

FIG. 9C shows power transmission as a function of the number of twisted pair cables at a temperature of 25° C. and a current of 0.25 A.

FIG. 9D shows power transmission as a function of the number of twisted pair cables at a temperature of 45° C. and a current of 0.25 A.

FIG. 9E shows power transmission as a function of the number of twisted pair cables at a temperature of 25° C. and a current of 0.18 A.

FIG. 9F shows power transmission as a function of the number of twisted pair cables at a temperature of 45° C. and a current of 0.18 A.

FIG. 10A shows power transmission efficiency estimation for different distances at 25° C.

FIG. 10B shows power transmission efficiency estimation for different distances at 45° C.

FIG. 11 shows Table I showing the power levels for power sourcing equipment and powered devices.

### DESCRIPTION OF INVENTION

Brownfield installations are likely to have a plurality of CTPC operating with PoE. Those cables could be replaced with hybrid cables (fiber and copper) when bandwidth or reaches need to be increased. Installing small-diameter pure optical fiber cables, instead of bulky hybrid cables, would be preferred. However, optical fiber cannot transmit efficiently and safely the amount of power needed to energize Ethernet equipment.

In those circumstances, decommissioning and removing copper cables can be costly, time-consuming, and can have a significant environmental impact and increase risks of damaging adjacent cabling. A more sustainable approach is to only install optical fiber cables and to utilize a more efficient method for transmitting power over the already available copper conductors as shown in the following example.

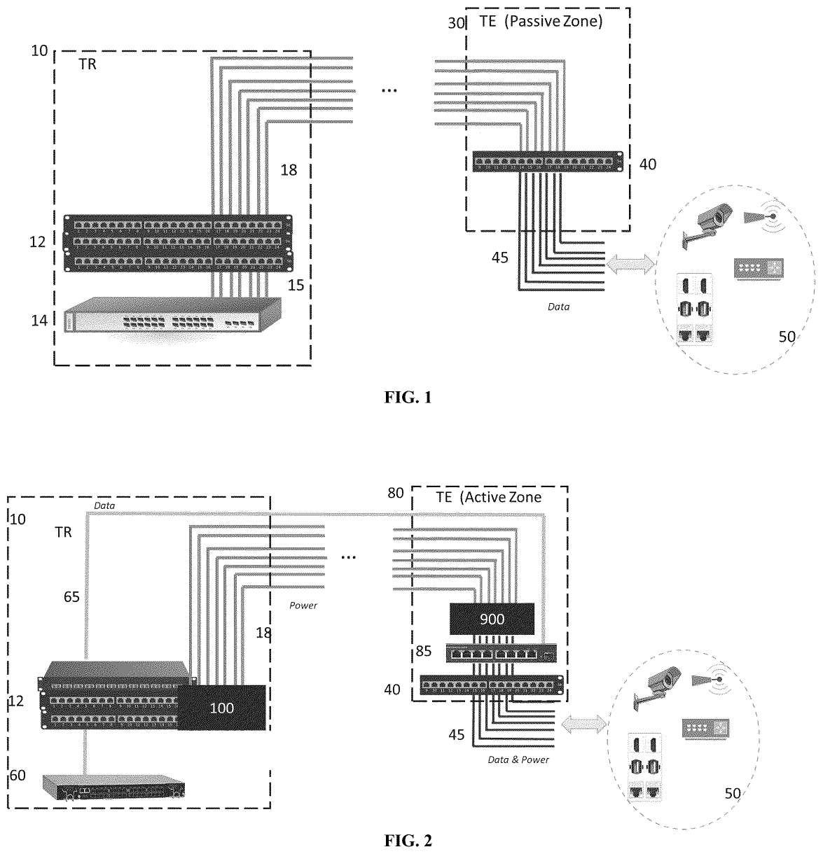

In FIG. 1, 10 represents the TR, 12 the patching components (path panels, enclosures, cassettes), 14 the distribution or aggregation switch, 15 copper patch cables and the horizontal CTPCs 18 connecting the TR to a passive ZE 30. The ZE 30 contains a patch panel 40 that connects 18 to the CTPCs 40. The cables 40 connect to the devices 50 providing data signals.

In FIG. 2, a migration from PZC 30 to AZC 80 by reusing the copper cables is shown. In this example, the data transmission functions provided by the CTPC 18 are replaced by an optical fiber cable 65 that connects the downlinks or a TR switch 14 to the uplinks of a small switch 85 installed in the ZE. The fibers in 65 transmit only data. The cables 18 are connected to a PSE frame 100 designed to operate with multiple CTPCs, of diverse types, complying with requirements of voltage, power, and temperature rise defined by standard organizations such as IEEE or NFPA, and UL, among others. The PSE frame 100 connects to a plurality of power receivers 900 that converts the DC to the powered device required values and distribution power among multiple ports. In FIG. 2, only one power receiver 900 is shown. Other ports of PSE frame 100 are connected to power receivers 900 in other enclosures (not shown). Since the PSE frame 100 only needs to transmit power and not data signals as a PoE PSE, and the power can be distributed among a larger number of CTPC, the current and the power dissipated per conductor can be reduced, improving the efficiency of the system relative to PoE. Also, the PR 900 in the active ZE powers a smaller and more efficient POE switch located close to the devices 50, reducing the dissipation losses of cables, e.g., 45.

A DC PSE, that is only dedicated to transmitting DC power of a fixed polarity (no data signal) can be significantly less complex and more efficient than the current PoE systems for various reasons.

PoE systems, e.g., the ones based on 802.3 bt, need to meet compatibility with prior generation PoE systems and connection schemes. Therefore, the PoE systems are required to accept different voltage levels, e.g., from 37V to 57V DC but also various polarities of the power supply (positive or negative supply polarity which adds loss or complexity relative to a DC source. Also, PoE PSEs are not designed to operate over multiple cables.

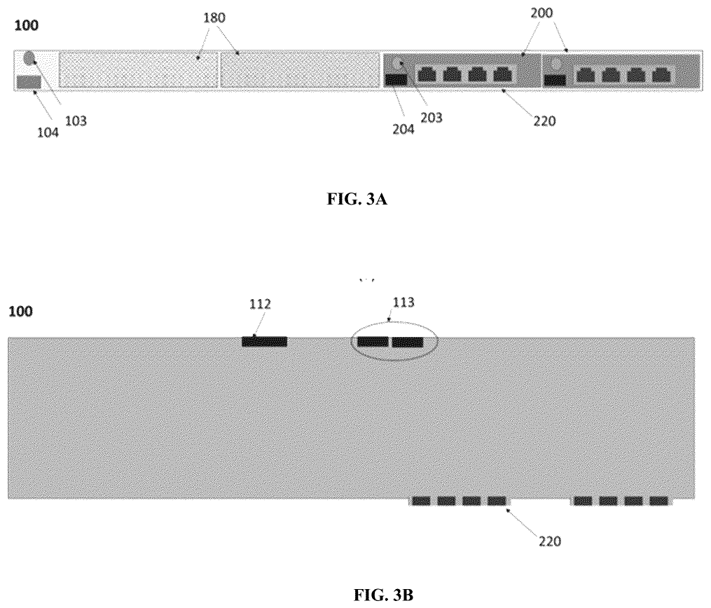

FIGS. 3A and 3B show the front view and top view of a frame and modular PSE embodiment. In this figure, a PSE frame 100, which can fit in ≥1 RU of a rack of an enclosure, can accommodate more than four PSE 200. The PSE frame 100 shown in the figure has four slots 180, each can accommodate one PSE module 200. Each PSE module 200 with four RJ45 ports 220 as shown in the figure can provide an aggregated power of ≤250 W of power to the connected CTPCs. Each PSE module 200 with eight RJ45 ports as shown in the figure can provide an aggregated power of ≤500 W of power to the connected CTPCs. The PSE frame 100 has indicators 103, e.g., LEDs, control interfaces 104 and connectors to external AC power 112. Controls interfaces 113 to connect to a computer or external controller can be implemented using USB-C or RJ-45 ports. The PSE module 200 has indicators 203, e.g., LED, and control interfaces 204.

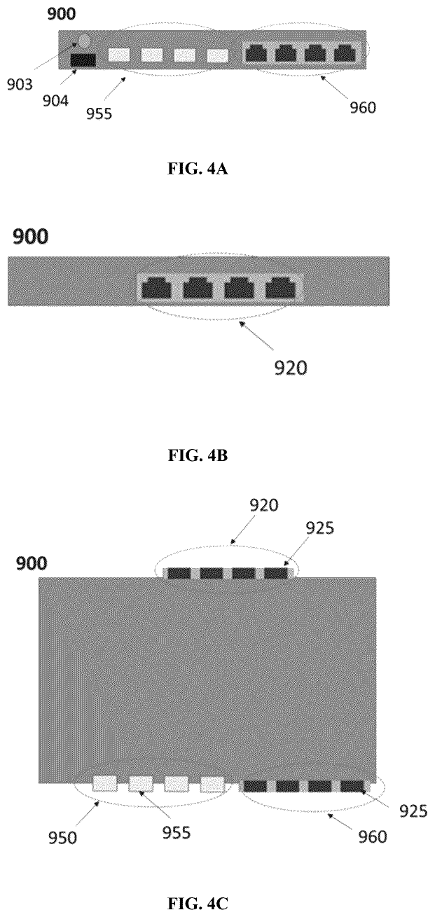

FIGS. 4A and 4B show the front view and top view of a frame and modular PR embodiment. In this figure, a PR 900, which can fit in ≥1 RU of a rack of an enclosure has input ports 920 consisting of four to eight RJ-45 ports 925.

In the shown embodiment, 950 and 960 are the output ports. In the figure, 950 consists of four ports 955, e.g., phoenix connector, which can provide DC power to an access switch 85 or other devices such as a wireless access point. The PR 900 can optionally contain an internal PoE source, that will provide PoE power over the 960 ports, where each port 925 is an RJ45.

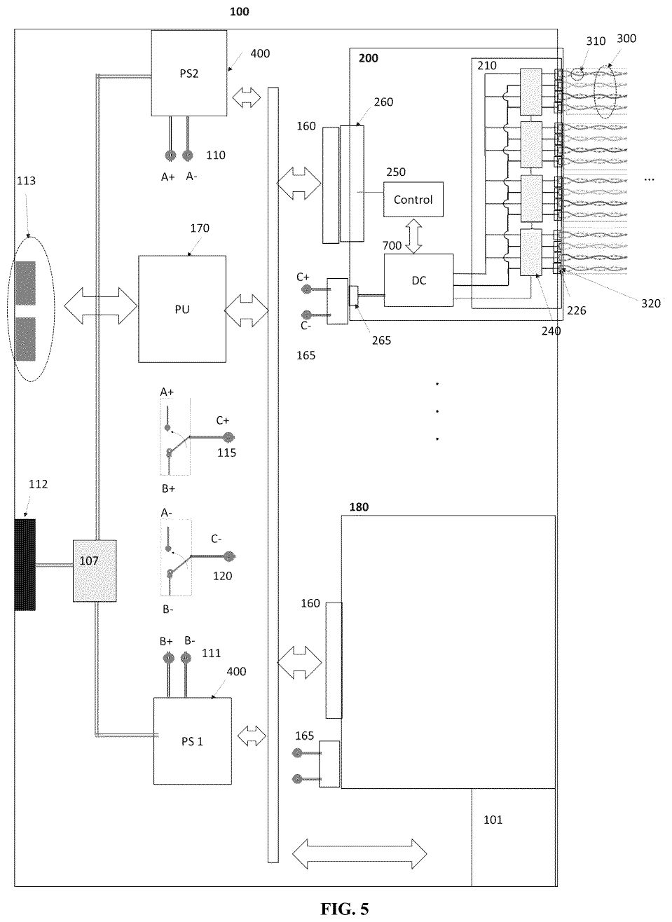

The internal elements of the 100 PSE frame, PSE module 200, and PR 900 are shown in FIG. 5. PSE frame 100 contains two identical power supplies 400 connected through copper circuits to surge protections and interruption circuits represented by 107. Element 107 is connected to the external AC power using connector interface 112 and contains electrical filters made by capacitors and inductors to clean the noise of the AC inputs.

The power supply 400 converts AC, e.g., ˜120 V AC, to DC power, e.g, 57 or 60 V, and can be implemented using efficient switching AC/DC converters, instead of only simple full-wave rectifiers.

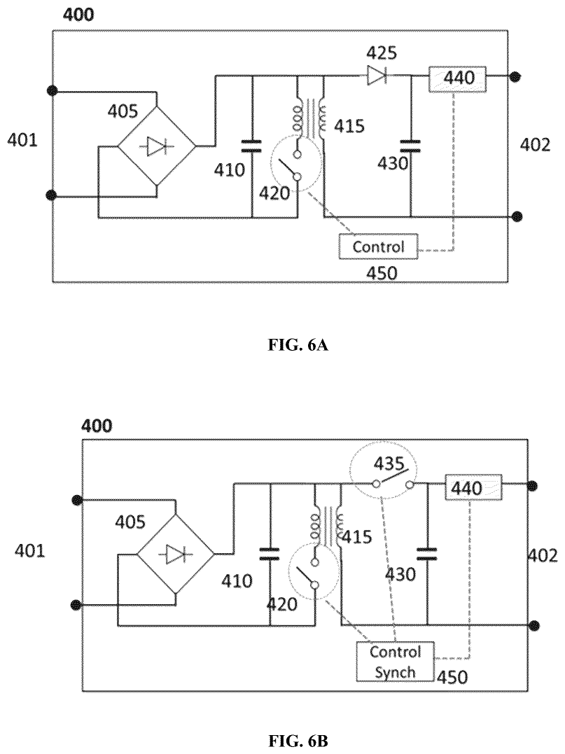

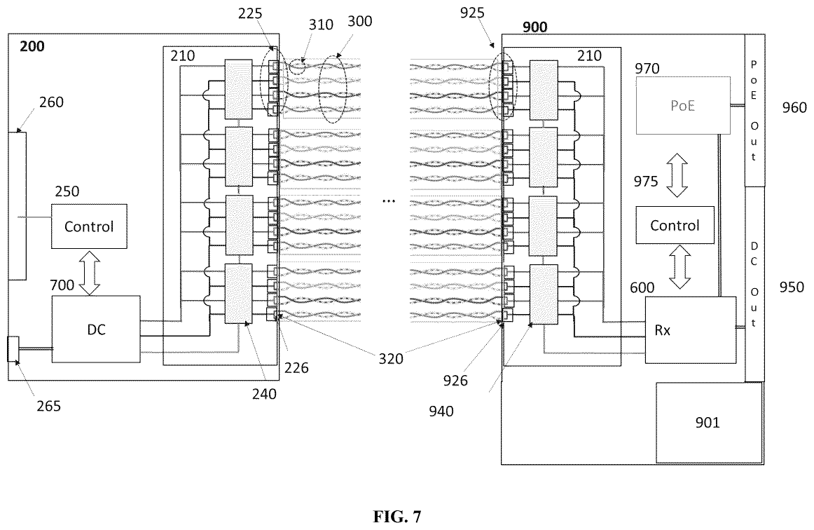

FIGS. 6A and 6B show implementation examples for PSE module 400. In FIG. 6A, 401 and 402 represent the input and output ports (note 401 after 107 could have some degree of noise filtering). The diode bridge 405 should meet the required voltage e.g, for 120 V AC, 405 should be able to operate at least 42% higher voltage, in this example, at 170 V. The capacitor 410 smooths the voltage rectified by 405, so it should meet similar voltage criteria. A switching element 420, which can be implemented using metal-oxide-semiconductor field-effect transistors, MOSFETs, or Insulated-gate bipolar transistors, IGBTs, operate at a switching frequency in the order of tens of kHz. The switch element 420 generates a periodical square wave on the primary side of the high-frequency transformer 415. The power is transmitted to the secondary of transformer 415 and rectified by diode 425. A capacitor 430 smooths and converts the signal to the required DC output voltage provided by port 402. Typically, for a specified output voltage in 402, e.g., 60V DC, the switching element 420 operates at a constant periodicity (frequency), using pulse-width modulation (PW), the duty cycle to produce the required voltage. The sensing component 440 connects to a control element 450 which regulates the pulsed width signal that feeds the switch 420. The circuit described in FIG. 6A provides better efficiencies than standard full-wave rectifiers without switching elements. The efficiency can be improved even more by replacing the diode 425 with another switching element 435 with operates in synchrony with 420 as shown in FIG. 6B. PSE using switching AC/DC converters can achieve efficiencies over 92% at 50% load and better than 94% at 100%.

Higher efficiencies can be achieved by removing the diode bridge 405 and using synchronous converters. For example, a totem-pole bridgeless, which separates the conversion into two sections: one for power factor correction and another for DC/DC conversion, replaces the diode bridges with a set of MOSFETs switching in a synchronized way to provide the required voltage with efficiencies >95%.

The outputs of the power supply unit 400 shown in FIGS. 6A and 6B are represented by A+/A− and B+/B−. Switching devices 115 and 120 determine the state of the redundant power sources as active or standby. The output of the devices 115 and 120, C+/C− provides power to the inserted PSE modules 200 in slot 180 through adapters/connectors 165. Adapters/connectors 165 provide the power to adapters/connector 260 of the PSE module 200, only when PSE frame 100 detects and identifies that PSE module 200 in operational state through handshake protocols.

The protocols for sensing and identifying PSE modules 200 are performed in the processing unit, PU 170, which consists of a processor, memory, and associate circuits to control functionalities of the PSE Frame 100. PU 170 communicates through communication circuits or busses to the different internal components of PSE Frame 100. PU 170 interfaces to connected module PSE 200, specifically module controller 250, through port 160. The PU 170 also interfaces with unit 101, which controls I/O functionalities such as displays and user interface buttons 103 and 104.

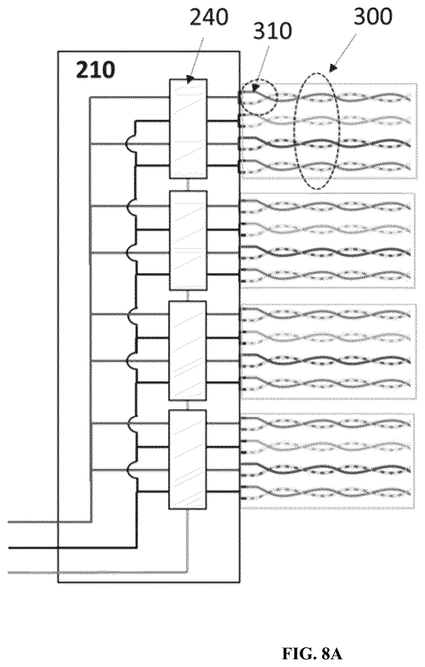

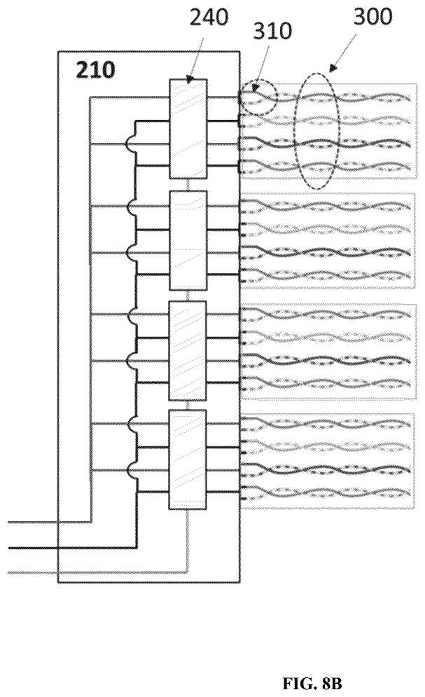

FIG. 7 shows the elements of PSE module 200 and PR 900 and how they transmit power and communicate low bandwidth controlling signals through several CTPCs 300. As shown in the figure, the PSE module 200 contains a front-end 210 that interfaces with the CTPCs 300, providing different wiring schemes. For sake of simplicity in this figure, we show one that divides the pairs 310 of all CTPCs 300 connected to ports 225 in two paths, assigned to the positive and negative polarity of the DC power. This wiring scheme allows to reutilize CTPCs with different conductor sizes, e.g., 23 AWG, 24 AWG, 26 AWG, since the wire mixing balance the resistance of the positive and negative circuit paths. Another wiring configuration for the front end 210 is shown in FIG. 8B where the individual conductor of each twisted pair is grouped and assigned to positive and negative paths. The latter front-end configuration 210, although more complex, provides even better balance and noise isolation than the first one shown in FIG. 8A. In other embodiments, the front end 210 can have switching elements, enabling switching the wiring configuration.

The PSE module 200 in FIG. 7, interfaces to PSE frame 100 using ports 260 and 265 for control signals and power, respectively. The processor unit 250 controls a variety of functions of the PSE module 200, such as sensing and interrupting operations of the sensor/interrupter devices 240. The current sensor can be implemented by low-cost methods using resistors or Hall Effect current sensors. The PSE module 200 contains at least one device 240 per RJ-45 port 225. A DC component 700 contains sensors and breakers to interrupt the power flow from PSE frame 100 to PSE module 200. This component 700 can contain optionally a DC/DC converter to change the voltage from the PSE frame 100, e.g., 57V, to another voltage ≤60V.

FIG. 7 also shows the PR 900 elements such as the front-end 910, with a wiring configuration identical to 210 in the PSE module 200. Ports 925 are RJ-45 plugs or adaptors that interface with the CTPCs 300. It should be noted that as long as PSE module 200 and PR 900 use the same wire configuration in the front end 210, the connection order of the cables can be different between them. For example, a UTP cable can be connected to port 1 in the PSE module 200 and port 4 in the PR module 900, making the system more robust to connection errors.

The PR 900 contains a 600 element that receives the aggregate power from 910 to monitor power values and receive/transmit control signals from/to the PSE module 200. Optionally, it includes a POE injector 970 that follows the IEEE 802.3 protocols classes shown in Table I to communicate PoE devices. A controller 970 process information from sensor 940 and all the other functionalities of the receiver module. It also connects to device 901, which controls the display and I/O interfaces 903 and 904. For the less expensive PR 900 embodiment, the 970 PoE and port 960 are removed and leave those functionalities to a POE switch 85. In FIG. 2, this POE switch 85 is DC powered by the PR 900.

The PSE module 200 and received by PR 900 can enable power transmission over multiple CTPCs, while maintaining lower voltage and low-temperature increases, which permit the use of installed-based cable, e.g., UTP, of diverse conductor size, without requiring replacing them with compliant LP cable. Faster and less expensive upgrades of brownfield networks requiring converting passive to active zones can be done just by adding PSE frame 100, PSE module 200, and PR 900 and reusing installed cable. The system consisting of the PSE and PR elements enable efficient power transmission under diverse conditions, e.g., temperature, and current.

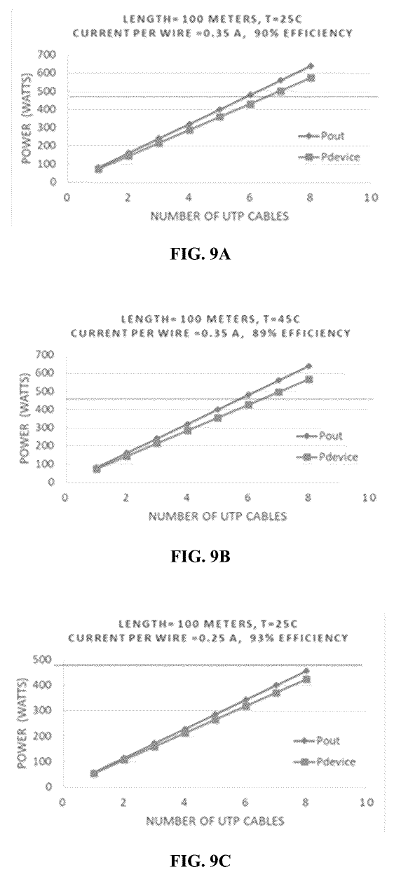

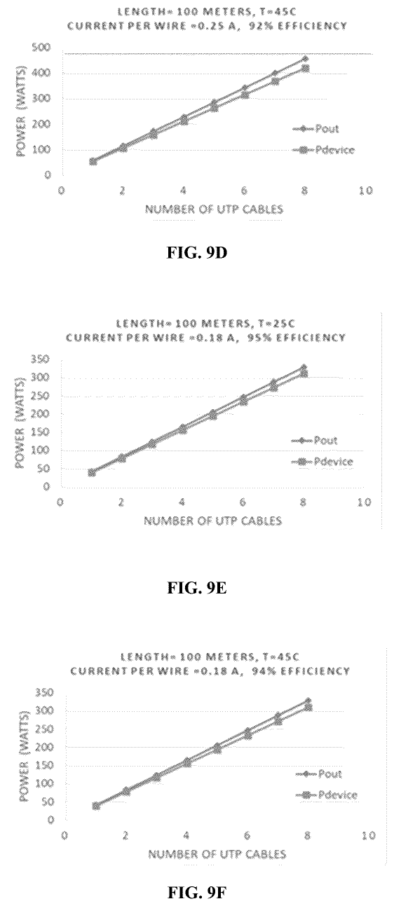

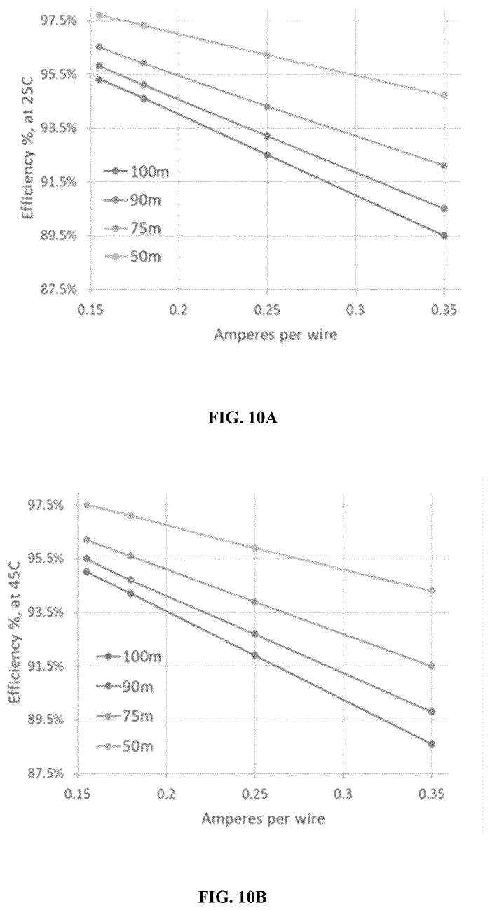

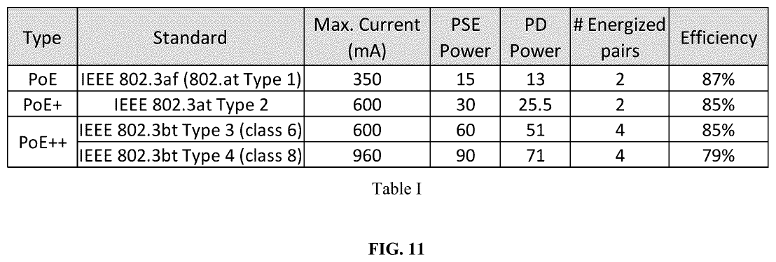

FIGS. 9A-F show the power transmitted by PSE module 200 and received by PR 900 for three different currents ≤0.4 A and a voltage of 57 V DC at two operating temperatures. In the figures, the vertical axis represents the aggregated power of several CTPCs, and the horizontal axis, the number of CTPCs. The line with diamond markers represents the power transmitted by the PSE module 200 to the cables and the line with square markers the power received by the PR 900. For example, FIG. 9A shows that the maximum power for currents per conductor of 0.35 W exceeded 500 W with 8 cables. However, in order to limit the cable transmitted power to ≤60 W, the current is reduced to ≤0.26 A. FIGS. 9(b) and (c) show the power by PSE module 200 and received by PR 900 for currents equal to 0.26 A and 0.18 A. It can be seen that with 4 CTPCs, the power at the device can be close to 200 W for currents 0.25 A. For currents ≤0.26 A, the temperature has a small effect on the received power. The dependence of the efficiency vs. cable length, temperature, and transmit current per conductor is shown in FIGS. 10A-B.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for repurposing a communications zone enclosure, comprising:
providing an input power source within a telecommunications room;
providing circuitry configured to split the power of the input source into a plurality of channels;
using pre-existing twisted pair communication cables to transmit power from the plurality of channels to the zone enclosure; and
recombining power the power into a single output power source.

2. The method of claim 1, further comprising running at least one fiber optic cable to the zone enclosure to provide data signals to equipment powered by the output power source.

3. A power source system, comprising:
a first main body frame having a front face; a rear side; a left side; and a right side;
a plurality of slots within the first main body frame, where one or more pluggable multi-port power transmitters can be inserted;
at least one internal power supply within the first main body frame connected to the AC grid that has DC outputs;
internal circuits within the first main body frame, including a processing unit to control the magnitude of supplied DC voltage and current, wherein the internal circuits of the main body frame apparatus connect to the slots;
pluggable multi-port power transmitter units having a front face; a rear side; a left side; and a right side;
a plurality of RJ45 adapters, where connectorized twisted pair cables can be connected within the pluggable multi-port power transmitter;
internal electrical sensors and controllers within the pluggable multi-port power transmitters that communicate with the processor of the main body frame;
circuits within the pluggable multi-port power transmitter to split the transmitted DC power among the connected cables; and
a remote multi-port power receiver wherein the multi-port power transmitter units transmit power to a remote multi-port power receiver using twisted pair communication cables, wherein the pluggable multi-port power receiver has a front face; a rear side; a left side; and a right side, wherein one face has a plurality of RJ45 adapters where connectorized twisted pair cables can be connected, and further, wherein the pluggable multi-port power receiver unit combines the power from multiple cables.

4. The power source system of claim 3, where the multi-port power transmitter units have circuits to split the transmitted DC power among the connected cables, where individual wires of the pair carry identical electrical polarity.

5. The power source system of claim 3, where the multi-port power transmitter units have circuits to split the transmitted DC power among the connected cables, where individual wires of the pair carry different electrical polarities.

6. The power source system of claim 3, where data from sensors and processor of the main body frame and multi-port power transmitter are used to detect if pluggable multi-port power transmitter units are connected in the slot multi-port power receiver.

7. The power source system of claim 3, where data from sensors and processor of the main body frame and multi-port power transmitter are used to regulate the transmitted voltage and current.

8. The power source system of claim 3, where algorithms data from sensors and processor of the main body frame or multi-port power transmitter are used to detect if pluggable multi-port power transmitter units are connected in the slot multi-port power receiver.

9. The power source system of claim 3, where data from sensors and processor of the main body frame or multi-port power transmitter are used to regulate the transmitted voltage and current.

10. The power source system of claim 3, that can transmit DC power among where the multi-port power transmitter units transmit power to a remote multi-port power receiver using twisted pair communication cables of size in the range of 20 AWG to 28 AWG.

11. The power source system of claim 3, where multi-port power transmitter units and remote multi-port power receiver units communicate through the twisted pair cables to coordinate power delivery.

12. The power source system of claim 3, where the main frame with at least four multi-port power transmitter units can fit in one rack unit (1.75 inches).
